(19) United States
(12) Patent Application Publication
(10) Pub. No.: US 2013/0095242 A1
(43) Pub. Date: Apr. 18, 2013

(54) Continuous Deposition System

(71) Applicant: Sharone Zehavi, San Jose, CA (US)

(72) Inventor: Sharone Zehavi, San Jose, CA (US)

(73) Assignee: INTEGRATED PHOTOVOLTAIC, INC., San Jose, CA (US)

(21) Appl. No.: 13/273,175

(22) Filed: Oct. 13, 2011

(51) Int. Cl. C23C 16/44; C23C 16/56

(52) U.S. Cl. 427/248.1; 118/719

(57) ABSTRACT

The invention discloses a method and system for continuous deposition of thin films by chemical vapor reaction for the purposes of semiconductor device fabrication; in some embodiments a device is a photovoltaic device.

### CROSS-REFERENCE TO RELATED APPLICATIONS

This application is related in part to U.S. application Ser. Nos. 12/074,651, 12/720,153, 12/749,160, 12/789,357, 12/860,048, 12/950,725, 12/860,088, 13/010,700, 13/019,965, 13/073,884, 13/077,870, 13/214,158, 13/234,316, 13/268,041, 13/272,073, and U.S. Pat. No. 7,789,331 all owned by the same assignee and all incorporated by reference in their entirety herein. Additional technical explanation and background is cited in the referenced material.

### BACKGROUND OF THE INVENTION

1. Field of the Invention

The invention discloses a method and system for continuous deposition of thin films by chemical vapor reaction for the purposes of semiconductor device fabrication; in some embodiments a device is a photovoltaic device.

2. Description of Related Art

The instant invention teaches an atmospheric pressure, chemical vapor deposition system for deposition of silicon based compounds. Prior art in this area is found in U.S. Pat. No. 4,834,020, U.S. Pat. No. 5,076,207, U.S. Pat. No. 5,122,391, U.S. Pat. No. 5,113,789, U.S. Pat. No. 5,122,391, U.S. Pat. No. 5,136,975, U.S. Pat. No. 5,393,563, U.S. Pat. No. 5,683,516, U.S. Pat. No. 5,849,088, U.S. Pat. No. 5,863,337, U.S. Pat. No. 5,863,338, U.S. Pat. No. 5,944,900, U.S. Pat. No. 6,143,080, U.S. Pat. No. 6,220,286, U.S. Pat. No. 6,231,673, U.S. Pat. No. 6,890,386, U.S.20060141290, U.S.20110195207; all incorporated herein in their entirety by reference.

U.S.20110195207 discloses a roll-to-roll atmospheric pressure chemical vapor deposition system for the deposition of graphene on a metal substrate comprising a grapheme forming unit comprising one or more gas nozzles and a temperature controllable heating jacket operable to a temperature between about 300° C. and about 2000° C. Rollers may be provided at the inlets and outlets to assist with a “roll-to-roll” operating mode; deposition is typically done on a metallic substrate. No provision is made for preventive maintenance or chamber replacement.

U.S. Pat. No. 4,834,020 discloses a APCVD system having a heated muffle and conveyor belt and a deposition zone with a gas injector assembly for each deposition zone. S. Reber of the Fraunhofer Institute has disclosed a high throughput deposition APCVD tool at the 24^{th} Eurpean PV Solar Energy Conference, 21-25 Sep., 2009, Hamburg, Germany. The Fraunhofer apparatus comprises three independent modules, each module having a double track of six 156 mm by 156 mm substrates; each module is in a muffle of low-permeability graphite; each muffle heated by a graphite rod resistance heater. Each module has two consecutive reaction chambers. Chlorosilane consumption is projected at 500g/min. with a deposition rate of 3 microns/min providing a 20 micron thick layer on 30 m²/h. This calculates to a silicon “utilization” of about 17%; utilization is defined as amount of silicon deposited on a substrate divided by amount of silicon entering the reactor. The reactor is also described in SCHILLINGER, K., et al.; “Crystalline SiC deposited by APCVD as a multifunctional intermediate layer for the recrystallised wafer equivalent”; 25th European PV Solar Energy Conference, Sep. 6, 2010; Valencia, Spain.

A key feature of any processing apparatus is time spent in production versus time spent in maintenance, including cleaning. A critical feature of the disclosed invention is the simplicity of design and resulting ease of performing maintenance and cleaning. A critical problem with the prior art is low utilization of deposition source material and the resulting maintenance problems caused by frequent apparatus cleaning. The instant invention enables rapid chamber replacement and/or chamber addition by the flexibility of a removeable central chamber 24B.

### SUMMARY OF THE INVENTION

In some embodiments, as noted schematically in FIG. 1, a deposition apparatus, system 100, for deposition of layers of various elements and/or compounds comprises a first portion 10 for establishing a desired atmosphere about a substrate; a second portion 20 comprising an outer, elongated chamber 22, optionally, cylindrical and optionally of quartz, and second, inner, elongated chamber comprising three sections, 24A, 24B, 24C, optionally, of quartz, and optionally, a rectangular shape; a third portion 30 comprises means for heating 32, 34, 36, 38, operable to impose a temperature profile of predetermined variation along a portion of the chambers; a fourth portion 40 for exiting from the heated portion; and a fifth portion 50 for exiting from the apparatus; the disclosed deposition apparatus is operable for chemical vapor deposition, optionally, at atmospheric pressure, with discrete or flexible, semi-continuous substrates. In some embodiments system 100 is configured to deposit silicon and/or silicon-compounds resulting in a layer of silicon, and/or silicon carbide, optionally, on carbon foil; in some embodiments subsequent processing in a connected, or separate, deposition apparatus results in additional layers of silicon, carbon, other Group IV or Group III-V or II-VI materials; optionally, a recrystallization step may follow a deposition step.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a schematic view of an embodiment of the deposition system.

FIG. 2 is a schematic view of an embodiment of the deposition system showing separation of chambers 24 A, B and C.

FIG. 3 is a schematic view of an embodiment of the deposition system showing detail of interface between sections 10 and 20.

### DETAILED DESCRIPTION OF THE PREFERRED EMBODIMENTS

However, it is to be noted that the present disclosure is not limited to the embodiments and the examples but can be implemented in various other ways. In the drawings, parts irrelevant to the description are omitted for the simplicity of explanation, and like reference numerals denote like parts through the whole document.

In accordance with one aspect of the present disclosure, there is provided a deposition or coating apparatus wherein a substrate material is chosen from a group comprising carbon, graphite, graphite foil, glassy graphite, impregnated graphite, pyrolytic carbon, pyrolytic carbon coated graphite, flexible foil coated with graphite, glass, ceramic and silicon. In some embodiments a substrate is a plate, optionally about 150 mm square or larger; optionally a substrate is a semi-continuous sheet or tape moved through the deposition apparatus. In some embodiments a substrate is pushed through the deposition apparatus; in some embodiments a substrate is conveyed through the deposition apparatus on a means for conveying such as a flexible tape, optionally, graphitic.

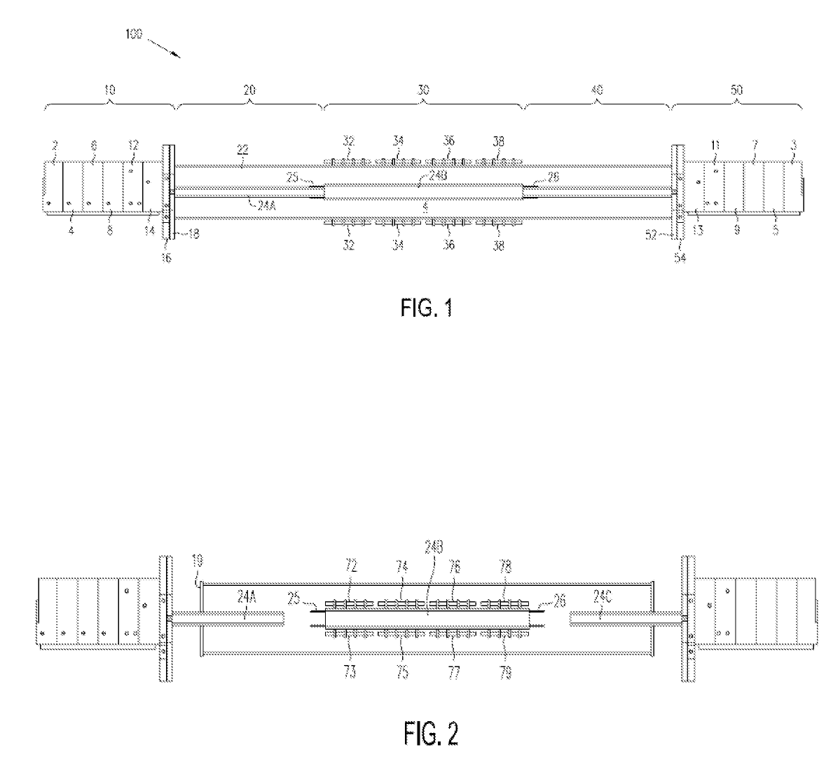

FIG. 1 shows schematically an embodiment of the disclosed CVD apparatus. A substrate, discreet or one or more semi-continuous strips, enters reactor 100 through entry portion 10. Entry portion 10 comprises a plurality of gas curtains wherein a process gas is introduced, for example, through sections 2, 6, 12 and exhausted through portions 4, 8, and 14 such that a minimum purity of process gas is achieved. Optionally, process and deposition gases are introduced in section 14. Exemplary process gases are hydrogen, nitrogen, argon, helium; exemplary deposition gases are silane(s), silicon-halogen bearing compounds, silicon-halogen-carbon bearing compounds, halogen compounds, dopant gases, including diborane, phosphine, and other gases known to one knowledgeable in the art. Entry portion 10 is attached to portion 20 by means for attachment 16, 18 and 19; means for attachment may comprise glass to metal seals; optionally, water cooled, and feedthroughs for gas(es), electrical and vacuum. Exit portion 50 is attached in a similar manner to portion 40 wherein means for attachment 52 and 54 provide similar functionality.

Portion 20 of CVD system 100 comprises outer, elongated chamber 22 and inner, elongated chamber section 24A; inner chamber 24 comprises three separable sections, 24A, 24B and 24C wherein sections 24A and 24C are detachable from section 24B. Coupling piece 25 enables section 24A to make contact and mate with upstream entrance of inner chamber section 24B; coupling piece 26 enables sections 24C to make contact and mate with downstream exhaust of inner chamber section 24B. Coupling pieces 25 and 26 provide a non-hermetic seal for the union of 24A to 24B and 24B to 24C; coupling pieces may also comprise a high temperature gasket of carbon fiber or high temperature Kapton® or Vespel®. Should process or deposition gases leak from the coupling sections the leak is contained in the interior of chamber 22 and exhausted through attachment means 16, 18, 19, 52 or 54. In some embodiments chamber 22 is maintained at a pressure somewhat higher than chamber 24B; in some embodiments chamber 22 is maintained at a pressure somewhat lower than chamber 24B; in some embodiments chamber 22 maintains a purge gas flowing through.

A key design feature is the fact that chambers 24 A, B and C can be replaced quickly when preventive maintenance, such as cleaning, is required. Additionally additional process chambers can be added either between portion 30 and 40 and/or between portions 40 and 50; alternatively portion 30 can be extended while also extending chamber 22.

In some embodiments additional chambers, not shown, 24A2, 24B2, 24C2, etc. may be added to enable additional processing steps such as oxidation, recrystallization and/or additional deposited layers. For instance in some embodiments a chamber 24A2 is added between 24A and 24B to heat a carbon substrate to a high temperature such that oxygen not purged through curtains 2, 4, 6, 8 and remaining in the process gases is reacted with a carbon based substrate. In some embodiments a chamber 24B2 is added between 24B and 24C to heat a deposited layer above its melting point such that large grained recrystallization occurs upon cooling as disclosed in U.S. Ser. No. 13/234,316.

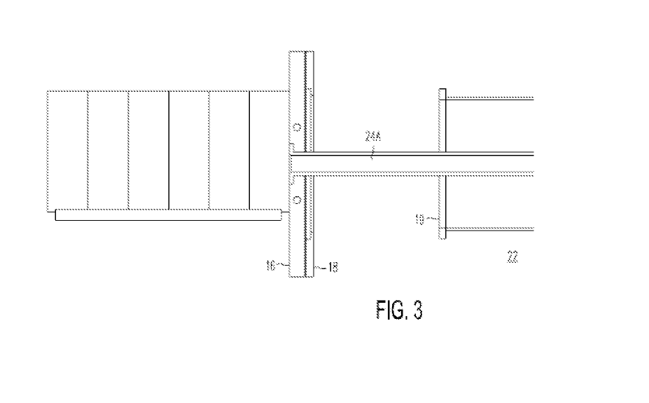

Portion 30 of CVD system 100 comprises outer, elongated chamber 22, inner, elongated chamber section 24B and means for heating comprising means 32, 34, 36 and 38, all operable for continuous deposition of a thin film onto one or more substrates traversing chamber 24B from entrance to exit. In some embodiments means for heating is circumferential about exterior of chamber 22, as shown; in some embodiments means for heating is circumferential about exterior of chamber 24B, shown in FIG. 2 as 72-79; in some embodiments means for heating is a planar source exterior to chamber 22, not shown; optionally, means for heating is two planar sources exterior to chamber 22 such that two substrates may be heated; in some embodiments means for heating is a planar source exterior to chamber 22 comprising a means for focusing optical energy onto a substrate. In some cases planar source(s) may be internal to chamber 22 and external to chamber 24B. Means for heating 32, 34, 36 and 38 and 72-79 comprise one or more means for heating chosen from a group comprising lasers, LEDs, lamps, flash lamps, halogen lamps, radiant sources, resistant sources, RF, microwave, IR sources and others known to one knowledgeable in the art. In some embodiments means for heating 32-38 or 72-79 are a multiplicity of independent means operable such that a temperature profile may be imposed upon a substrate in chamber 24B ranging from about 200° C. or greater at the upstream entrance region to a maximum of about 1430° C. and then declining to less than about 500° C. at the downstream exit end; in some embodiments a means for cooling may be added to facilitate a more rapid cool down.

Portion 40 of apparatus 100 provides for at least radiant cooling of a substrate and a transition to exit portion 50 by means for attachment 52 and 54 comprising glass to metal seals; optionally, water cooled, and feedthroughs for gas(es), electrical and vacuum. Portion 50 comprises a process gas exhaust 13 and a plurality of gas curtains 3, 7, 11 and exhausts 9 and 5.

During periods of preventive maintenance or repair portions 10 and 20 of CVD system 100 are detachable from portion 30 by withdrawing chamber 24A from coupling section 25; external brackets, not shown, may assist in maintaining chamber 24A inserted in coupling piece 25 and in proximity to chamber 24B. Similarly portion 24C can be withdrawn from coupling piece 26 and chamber 24B.

In some embodiments a thin film of silicon is deposited onto a carbonaceous substrate and subsequently converted to SiC, optionally in chamber 24B, 24B2 or chamber 24C or chamber external to apparatus 100. In some embodiments a thin film of silicon and carbon is deposited on a substrate as SiC. In some embodiments a thin film of carbon is deposited and reacts with a silicon based or coated substrate; optionally, converted to SiC in chamber 24B or a subsequent chamber. In some embodiments a thin film of silicon is deposited onto a silicon based substrate.

FIG. 2 Shows chambers 24A and 24C separated from chamber 24B in preparation for chamber cleaning or replacement or additional chambers to be installed. Means for heating, 72-79 is shown about chamber 24B. Means for heating may be attached to chamber 24B in a circumferential manner or as planar elements covering the top and bottom.

FIG. 3 shows the detail of interface portion between portion 10 and 20. Chamber 22 is secured through interface plate 19 to plate 18; plate 18 is attached to interface plate 16 which also interfaces with chamber 24A.

In some embodiments deposition system 100 operates in a horizontal mode for processing rigid substrates or a single flexible, semi-continuous substrate. In some embodiments deposition system 100 is operable in a vertical mode for processing a single flexible, semi-continuous substrate or more than one flexible, semi-continuous substrates. When deposition system 100 is oriented vertically and processing two continuous substrates gas curtain supplies 2, 6, 12, 11, 7, 3, gas curtain exhausts 4, 8, 9, 5 and process gas supply 14 and process gas exhaust 13 may be duplicated such that a set of supplies and exhausts is dedicated for each continuous substrate.

In some embodiments deposition system 100 is operable as a hot-wall CVD reactor wherein first means for heating 32, 34, 36 and 38 are located external to chamber 22; optionally, a second or alternate means for heating 72, 73, 74, 75, 76, 77, 78, 79 is located external to chamber 24B of FIG. 2. In some embodiments a second means for heating comprise one or more from a group comprising lasers, LEDs, lamps, flash lamps, halogen lamps, radiant sources, resistant sources, RF, microwave, IR sources and others known to one knowledgeable in the art.

In some embodiments deposition system 100 is operable as a cold-wall CVD reactor wherein first means for heating 32, 34, 36 and 38 are located external to chamber 22; optionally, second or alternate means for heating 72, 73, 74, 75, 76, 77, 78, 79 are located external to chamber 24B of FIG. 2. In these embodiments first and/or second means for heating may be radiative heaters, such as lamps or lasers; optionally, a RF inductive type or microwave or IR source may be used; chambers 24A, B and C may be of quartz or other transmissive material. In some embodiments the composition of chambers 24A, 24B and 24C are not the same; exemplary chamber materials for chamber 22 and 24 are silicon, Pyrex, glass, quartz, carbon, graphite, SiC, Al₂O₃, a high temperature metal, or other material known to one knowledgeable in the art.

In some embodiments chamber 24B and optionally, chambers 24B2, 24B3, 24B4 are operable to deposit a first layer, optionally, SiC, and a second layer, optionally, Si, and a recrystallization step wherein the recrystallization step has at least two temperature zones, a first zone above 1410° C. and a second zone below 1410° C. and above 1200° C., the portion of the substrate and deposited layers being in the second zone more than 0.5 seconds.

In some embodiments a method for forming a substantially continuous layer of silicon carbide between a carbon based substrate and a silicon layer comprises the steps selecting a carbon based substrate; depositing a first layer consisting of carbon and silicon of a first carbon/silicon ratio; optionally, the C/Si ratio may be zero; depositing the silicon layer consisting substantially of silicon; and recrystallizing at least a portion of the deposited silicon layer such that the mean lateral dimension of the recrystallized grains is greater than about 5 mm, optionally greater than about 10 mm; optionally, the recrystallization step is as described in U.S. Ser. No. 13/234,316; optionally, the deposited silicon layer is recrystallized such that the second layer is held at temperature above 1200° C. and below 1410° C. for longer than 5 seconds during the recrystallization.

In some embodiments a method of recrystallizing a layer of material comprises the steps: selecting a composite substrate with the layer deposited onto the substrate; advancing the substrate through first zone, S, such that a temperature, T_{S}, is established within at least a portion of the deposited layer wherein Ts is less than the melting point, T_{MP}, of the layer; advancing the substrate through second zone, I, such that a temperature, T_{I}, is established within at least a portion of the deposited layer wherein T_{I} is greater than T_{S}; advancing the substrate through third zone, M, such that a temperature, T_{M}, is established within at least a portion of the deposited layer wherein T_{M} is greater than T_{MP}; and advancing the substrate through fourth zone, R, such that a temperature, T_{R}, is established within at least a portion of the deposited layer wherein T_{R} is below T_{MP}, of the deposited layer and above a predetermined temperature, X*T_{MP}, for at least Y seconds wherein the substrate and layer are advanced through the first through fourth zones sequentially at a rate of about Q mm/sec. such that the temperature criteria of each zone is established within at least a portion of the deposited layer while that portion is physically within the respective zone; optionally, X is between about 0.99 and about 0.60; optionally, Y is between about 0.1 and about 30 seconds; optionally, the second zone comprises one or more means for heating chosen from a group consisting of a spot of radiation rapidly scanned over the substrate, a linear array of radiation projected onto the substrate, laser, flash lamp, resistance heaters, rf coils, microwave radiation, and infra-red heaters; optionally, the first and third zones comprise one or more means for temperature modulation chosen from a group consisting of a spot of radiation rapidly scanned over the substrate, a linear array of radiation projected onto the substrate, laser, flash lamp, resistance heaters, rf coils, microwave radiation, infra-red heaters and means for cooling comprising refrigeration coils, thermoelectric means, fans, and cooling coils; optionally, the deposited layer material is substantially one or more elements chosen from a group consisting of Group II, III, IV, V and VI elements; optionally, the second and third zone length combined are more than 5 mm long in the direction of substrate travel; optionally, the substrate advancing rate, Q, is at least 0.5 mm per second.

In some embodiments a solid state device comprises a composite substrate; and a first layer comprising material recrystallized by the method of U.S. Ser. No. 13/234,316; optionally, the first layer comprises material recrystallized such that more than 90% of the recrystallized layer has crystal grains of a size greater than 3 mm in any lateral dimension parallel to the substrate surface; optionally, the first layer comprises material recrystallized such that more than 90% of the recrystallized semiconductor layer has crystal grains of a size greater than 50% of the smallest lateral dimension parallel to the substrate surface; optionally, the recombination velocity is between about 50 cm/s and about 500 cm/sec; optionally, a solid state device is a solar cell wherein the recrystallized layer comprises a crystal grain at least 90% of the size of the irradiated area of the solar cell or at least 90% of the size of an individual cell in a large area solar module; optionally, the composite substrate is chosen from a group consisting of silicon, silicon composite with graphite, glass, ceramic, carbon, and a material coated with SiO₂ or SiC; optionally, a solid state device further comprises a barrier layer within the composite substrate and the first layer. In some embodiments a solar cell with a composite substrate and recrystallized layer has a conversion efficiency greater than 10%; optionally, greater than 12%. As used herein, in some embodiments, a composite substrate is one disclosed in U.S. application Ser. No. 13/272,073, filed Oct. 12, 2011.

It will be understood that when a layer is referred to as being “on top of” another layer, it can be directly on the other layer or intervening layers may also be present. In contrast, when a layer is referred to as “contacting” another layer, there are no intervening layers present. Similarly, it will be understood that when a layer is referred to as being “below” another layer, it can be directly under the other layer or intervening layers may also be present.

In the previous description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention. In cases where reference is made to “an embodiment” or “one embodiment” or “some embodiments”, it is understood that embodiments may comprise one or more of the inventive features and/or limitations presented in the entire specification for all exemplary embodiments without regard to how a particular embodiment is described.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

I claim:

1. An apparatus for depositing a layer on a substrate by chemical vapor deposition comprising:
a first portion for establishing a desired atmosphere about a substrate;
a second portion comprising a first chamber and a second chamber interior to the first chamber;
a third portion comprising a means for heating operable to impose a temperature profile of predetermined variation along a portion of the second chamber;
a fourth portion for exiting from the third portion; and
a fifth portion for exiting from the apparatus; wherein the second portion connects the first portion to the third portion and the fourth portion connects the third portion to the fifth portion and wherein the second chamber comprises a first section, a second section and a third section such that the first section is detachable from the second section and the third section is detachable from the second section and the second section is operable to deposit the layer on the substrate.

2. The apparatus of claim 1 wherein the first chamber and the second chamber are maintained at about ±5 psig of atmospheric pressure.

3. The apparatus of claim 1 wherein the second section comprises a first part and a second part such that the first part is operable to deposit the layer on the substrate and the second part is operable to recrystallize at least a portion of the deposited layer such that the deposited layer is held at a temperature above 1200° C. and below 1410° C. for longer than 5 seconds during the recrystallisation.

4. The apparatus of claim 1 further comprising a means for heating located proximate and exterior the second section of the second chamber operable to impose a predetermined temperature profile on the substrate wherein the temperature profile may vary between about 200° C. and about 1430° C. along the second section of the second chamber.

5. The apparatus of claim 1 wherein the substrate is chosen from a group consisting of carbon, graphite, graphite foil, glassy graphite, impregnated graphite, pyrolytic carbon, pyrolytic carbon coated graphite, flexible foil coated with graphite, glass, ceramic and silicon.

6. The apparatus of claim 1 wherein the substrate is first and second flexible substrates moving in tandem through the apparatus and chosen from a group consisting of carbon, graphite, graphite foil, glassy graphite, impregnated graphite, pyrolytic carbon, pyrolytic carbon coated graphite, flexible foil coated with graphite, glass, ceramic and silicon.

7. A method for depositing a layer on a substrate;
selecting a substrate; and
depositing a first layer in the apparatus of claim 3 wherein the layer thickness is between about 0.1 microns and about 100 microns.

8. The method of claim 7 comprising the step:
recrystallizing at least a portion of the first layer such that the mean lateral dimension of the recrystallized grains is greater than about 10 mm.

9. The method of claim 7 comprising the steps:
depositing a second layer wherein the layer thickness is between about 0.1 microns and about 100 microns.
recrystallizing at least a portion of the second layer such that the mean lateral dimension of the recrystallized grains is greater than about 10 mm.

10. An apparatus for depositing a layer on a substrate by chemical vapor deposition comprising:
a first portion for establishing a desired atmosphere about a substrate;
a second portion comprising a first chamber and a second chamber interior to the first chamber wherein the first chamber and the second chamber are maintained at about ±5 psig of atmospheric pressure;
a third portion comprising a means for heating operable to impose a temperature profile of predetermined variation along a portion of the second chamber;
a fourth portion for exiting from the third portion; and
a fifth portion for exiting from the apparatus; wherein the second portion connects the first portion to the third portion and the fourth portion connects the third portion to the fifth portion and wherein the second chamber comprises a first section, a second section and a third section such that the first section is detachable from the second section and the third section is detachable from the second section and wherein the second section comprises a first part and a second part such that the first part is operable to deposit at least one layer on the substrate and the second part is operable to recrystallize at least a portion of the deposited layer such that the deposited layer is held at temperature above 1200° C. and below 1410° C. for longer than 1 second during the recrystallization.

11. An apparatus for depositing layers on a substrate by chemical vapor deposition comprising:
a first portion for establishing a desired atmosphere about a substrate;
a second portion comprising a first chamber and a second chamber interior to the first chamber;
a third portion comprising a means for heating operable to impose a temperature profile of predetermined variation along a portion of the second chamber;
a fourth portion for exiting from the third portion; and
a fifth portion for exiting from the apparatus; wherein the second portion connects the first portion to the third portion and the fourth portion connects the third portion to the fifth portion and wherein the second chamber comprises a first section, a second section and a third section such that the first section is detachable from the second section and the third section is detachable from the second section and the second section is operable to establish a first and second deposition zone and a first and second temperature zone for recrystallization such that a first layer of SiC is deposited in the first deposition zone and a second layer of Si is deposited in the second deposition zone wherein the first temperature zone for recrystallization is maintained above 1410° C. and a second temperature zone for recrystallization is maintained between less than 1410° C. and above 1200° C., such that the substrate and deposited layers are in the second temperature zone more than 0.5 seconds.
